(19) United States
(12) Patent Application Publication
(10) Pub. No.: US 2008/0111230 A1
(43) Pub. Date: May 15, 2008

(54) WIRING FILM HAVING WIRE, SEMICONDUCTOR PACKAGE INCLUDING THE WIRING FILM, AND METHOD OF FABRICATING THE SEMICONDUCTOR PACKAGE

(75) Inventors: Goon-Woo KIM, Chungcheongnam-do (KR); Heui-Seog KIM, Chungcheongnam-do (KR); Sang-Jun KIM, Chungcheongnam-do (KR); Wha-Su SIN, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/937,299

(22) Filed: Nov. 8, 2007

(30) Foreign Application Priority Data
Nov. 10, 2006 (KR) 2006-0111226

(51) Int. Cl. H01L 23/485; H01L 21/56; H05K 1/00

(52) U.S. Cl. 257/700; 174/258; 438/108; 257/E23.019; 257/E21.502

(57) ABSTRACT

A wiring film including wires, a semiconductor package including the wiring film, and a method of fabricating the semiconductor package are provided. The wiring film comprises a base film and first wires arranged on a first surface of the base film. First bumps are respectively positioned at ends of the first wires. A first adhesive layer is also provided to cover the first wires and the first bumps.

### CROSS-REFERENCE TO RELATED PATENT APPLICATION

This application claims the benefit of Korean Patent Application No. 10-2006-0111226, filed on Nov. 10, 2006, in the Korean Intellectual Property Office, the disclosure of which is incorporated herein by reference.

### BACKGROUND

1. Field of the Invention

The present invention relates to an electrical connection between a semiconductor chip and a printed circuit board, and a semiconductor package including the same, and more particularly, to a wiring film to make the electrical connection and a semiconductor package including the wiring film.

2. Description of the Related Art

One of the fundamental stages of fabricating a semiconductor package is electrically connecting a pad of a semiconductor chip to an electrode of a printed circuit board. The connection is often made by wire bonding using gold (Au) wires or by using bumps. A flip chip package or a wafer level package uses bumps to electrically connect a pad of a chip to an electrode of a board.

However, wire bonding has a limit in reducing a loop height of a wire, and is thus not suitable for fabricating a very thin semiconductor package. In the flip chip package or the wafer level package in which the electrical connection is made using bumps, a redistribution layer needs to be formed to redistribute the interconnections so that the pads of the semiconductor chip match the electrodes of the board, which is expensive.

### SUMMARY

Embodiments of the present invention provide a wiring film that enables a semiconductor package to be thin, simplifies the fabrication process while reducing a unit price for the process, and improves reliability. Other embodiments of the present invention provide a semiconductor package including the wiring film and a method of fabricating the semiconductor package.

According to an embodiment of the present invention, a wiring film includes a base film and first wires arranged on a first surface of the base film. First bumps are respectively positioned on ends of the first wires. A first adhesive layer is also provided to cover the first wires and the first bumps.

### BRIEF DESCRIPTION OF THE DRAWINGS

The above and other features and advantages of the present invention will become more apparent by describing in detail exemplary embodiments thereof with reference to the attached drawings in which:

FIGS. 1A, 1B, and 1C show a wiring film according to an embodiment of the present invention:

FIG. 2 is a sectional view of a wiring film according to an embodiment of the present invention;

FIGS. 3A, 3B, 4A, 4B, and 4C show a semiconductor package and a method of fabricating the same according to an embodiment of the present invention; and

FIGS. 5 through 11 are sectional views of semiconductor packages according to embodiments of the present invention.

### DETAILED DESCRIPTION

The present invention will now be described more fully with reference to the accompanying drawings, in which exemplary embodiments of the invention are shown. This invention may, however, be embodied in many different forms, and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

Wiring Film

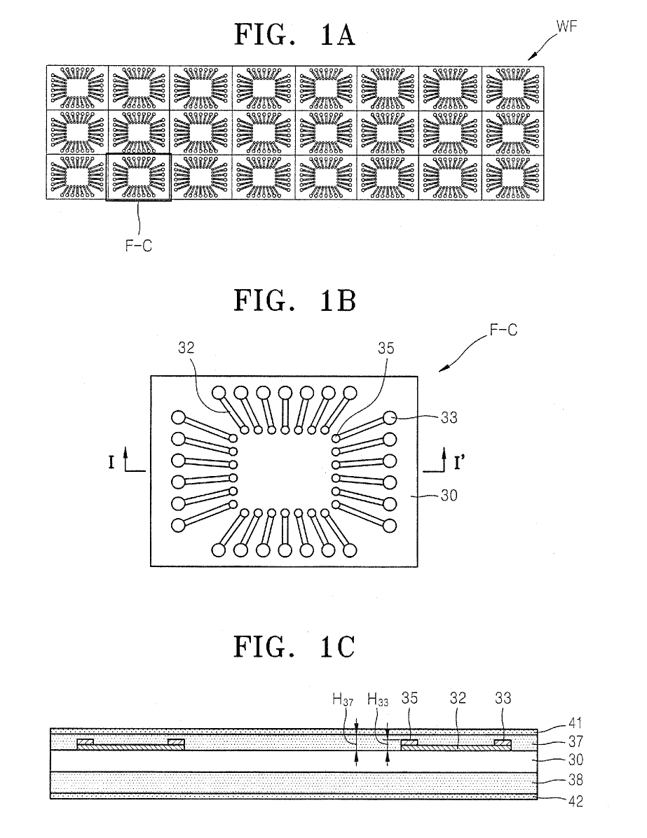

FIGS. 1A, 1B, and 1C show a wiring film according to an embodiment of the present invention. FIG. 1A is a plan view of the wiring film including a number of unit cells, FIG. 1B is a plan view showing an enlargement of the unit cell illustrated in FIG. 1A, and FIG. 1C is a sectional view taken along line I-I′ of FIG. 1B.

A wiring film according to an embodiment of the present invention, and a method of fabricating the wiring film, will now be described with reference to FIGS. 1A, 1B and 1C.

A base film 30 capable of including a number of unit cell regions F_C to be applied to a single package is initially provided. The base film 30 may be composed of a material which has high stability at high temperatures and good insulation, and which is rigid at room temperature but flexible at high temperatures. The base film 30 may be, for example, a polyimide film, a polyester film, or a polyamide film. Preferably, the base film 30 may be the polyimide film.

Wires 32 are formed on a first surface of the base film 30. The wires 32 may be formed by a printing, a jetting, or an imprinting process using a conductive material. These methods can more easily form wires with a small pitch as compared to wire bonding. The wires 32 may be formed of one or more metals, such as gold (Au), silver (Ag), copper (Cu), nickel (Ni), aluminum (Al), tin (Sn), lead (Pb), platinum (Pt), bismuth (Bi), and indium (In).

Bumps 33 and 35 are formed on at least one end of each wire 32. In the embodiment illustrated in FIGS. 1A to 1C, the bumps 33 and 35 are formed at respective ends of the wire 32. The bumps 33 and 35 may be formed of a conductive material, such as solder or gold. The bumps 33 and 35 may be formed by a dotting process. Accordingly, the bumps 33 and 35 are more easily formed with a small pitch than bumps formed on a printed circuit board. The wires 32 and the bumps 33 and 35 may be formed in the same pattern on each of the unit cell regions F_C of the wiring film WF.

A first adhesive layer 37 is formed on a first surface of the base film 30, to cover the wires 32 and the bumps 33 and 35. The height H37 of the first adhesive layer 37 from the first surface of the base film 30 may be equal to or greater than the height H33 of the bumps 33 and 35. Further, the height H37 of the first adhesive layer 37 may be about 1.1 times or less the height H33 of the bumps 33 and 35. Thus, in some embodiments the height H37 may be between about 1 and about 1.1 times the height H33. Accordingly, while protectively covering the wires 32 and the bumps 33 and 35, the first adhesive layer 37 may be pushed from an upper part of the bumps 33 and 35 by heat and pressure, so that the bumps 33 and 35 are electrically coupled to an electrode on the printed circuit board. The height H37 of the first adhesive layer 37 may be within the range of about 5 to about 30 μm.

A first protection film 41 is further formed on the first adhesive layer 37. The first protection film 41 may be detachable from the first adhesive layer 37.

In the presently illustrated embodiment, a second adhesive layer 38 is further formed on a second surface of the base film 30. The height of the second adhesive layer 38 may be equal to or greater than the height of the first adhesive layer 37. Specifically, the height of the second adhesive layer 38 may be about 16 to about 24 μm.

A second protection film 42 is further formed on the second adhesive layer 38. Like the first protection film 41, the second protection film 42 may be detachable from the second adhesive layer 38.

The wiring film WF in the above described constitution can be rolled for transport and handling. In these instances, the protection films 41 and 42 protect the adhesive layers 37 and 38, the bumps 33 and 35, and the wires 32.

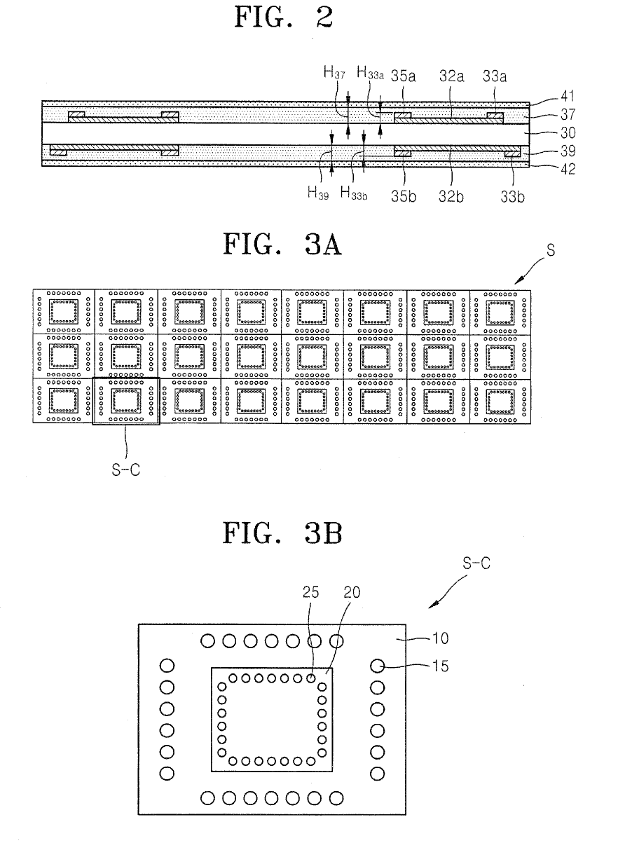

FIG. 2 is a sectional view of a wiring film according to an embodiment of the present invention. The wiring film according to the embodiment illustrated in FIG. 2 is similar to the wiring film according to the embodiment illustrated in FIGS. 1A through 1C, except for the following.

Referring to FIG. 2, a first wire 32a is formed on a first surface of a base film 30. First bumps 33a and 35a are formed on at least one end of the first wire 32a. A first adhesive layer 37 is formed on a first surface of the base film 30, to cover the first wire 32a and the first bumps 33a and 35a. A first protection layer 41 is formed on the first adhesive layer 37. The height H37 of the first adhesive layer 37 from the first surface of the base film 30 may be equal to or greater than the height H33a of the first bumps 33a and 35a. Further, the height H37 of the first adhesive layer 37 may be about 1.1 times or less the height H33a of the first bumps 33a and 35a.

A second wire 32b is formed on a second surface of the base film 30. Second bumps 33b and 35b are formed on at least one end of the second wire 32b. In the embodiment illustrated in FIG. 2, the second bumps 33b and 35b are formed at the respective ends of the second wire 32b. A second adhesive layer 39 is formed on the second surface of the base film 30, to cover the second wire 32b and the second bumps 33b and 35b. The height H39 of the second adhesive layer 39 may be between about 1 and about 1.1 times the height H33b of the second bumps 33b and 35b. A second protection film 42 is further formed on the second adhesive layer 39.

Semiconductor Package

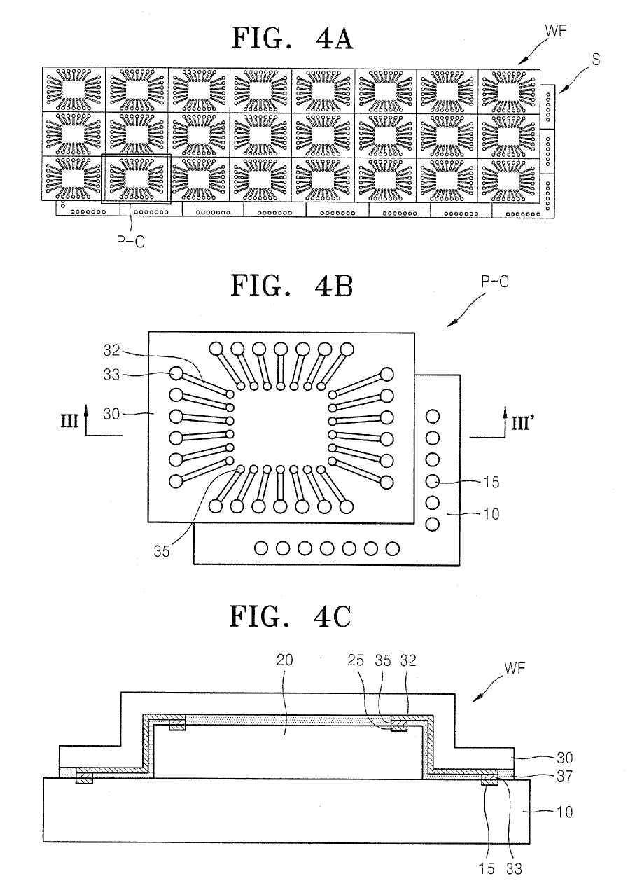

FIGS. 3A, 3B, 4A, 4B, and 4C show a semiconductor package and a method of fabricating the semiconductor package according to an embodiment of the present invention. FIG. 3A is a plan view of a printed circuit board including a number of unit cells, FIG. 3B is a plan view showing an enlargement of the unit cell illustrated in FIG. 3A, FIG. 4A is a plan view of a wiring film and a printed circuit board which are aligned, FIG. 4B is a plan view showing an enlargement of unit cells being aligned, and FIG. 4C is a sectional view taken along ling III-III′ of FIG. 4B.

Referring to FIGS. 3A and 3B, board pad electrodes 15 are arranged on each unit cell region S-C on a board 10 including a number of unit cell regions S-C. A semiconductor chip 20 including chip pad electrodes 25 is positioned in the middle of each unit cell region S-C. The board pad electrodes 15 may be arranged around the semiconductor chip 20.

Referring to FIGS. 4A, 4B, and 4C, a wiring film WF is arranged on the semiconductor chip 20 and the board 10. The wiring film WF may be any one of the wiring films of the embodiments described with reference to FIGS. 1C and 2. The wiring film WF may be cut from a bulk roll of film, to correspond to the size of the board 10. One or both of the protection films 41 and 42 may be removed from the wiring film WF. The wiring film WF and the board 10 are aligned so that bumps 33 and 35 of the wiring film WF correspond respectively to the pad electrodes 15 and 25.

Heat and pressure are applied to the wiring film WF, that is, the base film 30, to connect the bumps 33 and 35 respectively to the pad electrodes 15 and 25. During this process, a first adhesive layer 37 covering the bumps 33 and 35 is pushed from an upper part of the bumps 33 and 35 by the heat and pressure, so that the bumps 33 and 35 are respectively electrically coupled with the pad electrodes 15 and 25. In other words, if a portion of the first adhesive layer 37 covers the bumps, the heat and pressure of the connection process dispose this portion of the adhesive layer 37 so that bumps 33 and 35 are respectively electrically coupled with the pad electrodes 15 and 25.

The wiring film WF, which includes the base film 30 and the wires 32 arranged on the lower surface of the base film 30, is disposed on the board 10 during this connection process. During this process, the bumps 33 are electrically coupled to the board pad electrodes 15 and the bumps 35 are electrically coupled to the chip pad electrodes 25. The adhesive layer 37 arranged at both sides of the bumps 33 and 35 and covering the wires 32, the adhesive layer adhering the base film 30 to the board 10 and the semiconductor chip 20.

Then, the wiring film WF and the substrate S, which are electrically connected and bonded to each other, are then cut into unit packages P-C.

When the board pad electrodes 15 are electrically coupled to the chip pad electrodes 25 by the wiring film WF including the wires, a thin semiconductor package is possible since there are no problems associated with the wire bonding method, such as the limit in reducing the loop height of the wires. Additionally, the process cost is reduced since no redistribution layer is needed. Furthermore, when using the wiring film WF including the adhesive layer 37 on the bumps 33 and 35, no additional adhesive layers need to be formed between the wiring film WF and the board 10 or between the wiring film WF and the semiconductor chip 20. Since the adhesive layer 37 is arranged on both sides of the bumps 33 and 35, the electrical connection between the bumps 33 and 35 and the pad electrodes 15 and 25 is maintained even if the package is bent, thereby improving the reliability of the package.

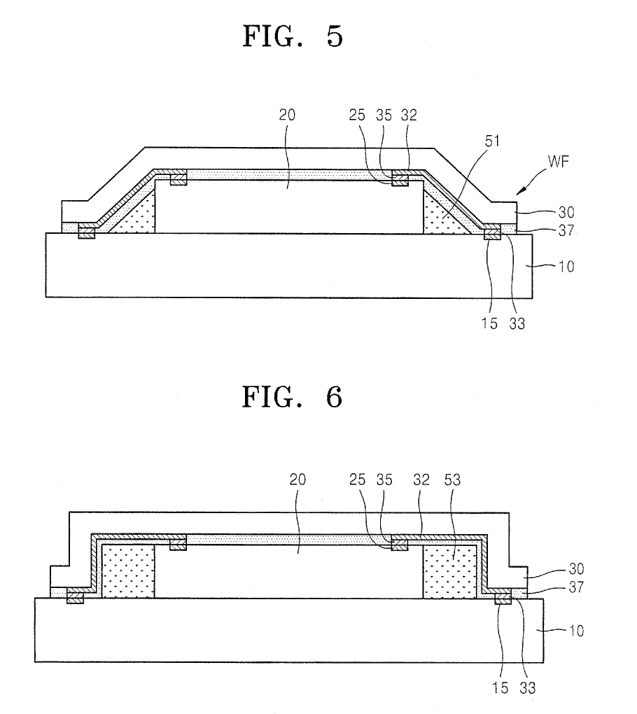

FIGS. 5 and 6 are sectional views of semiconductor packages according to embodiments of the present invention. The semiconductor packages of the embodiments of FIGS. 5 and 6 are similar to the semiconductor package described with reference to the embodiment illustrated in FIG. 4C, except for the following.

Referring to FIGS. 5 and 6, first supporting parts 51 and 53 are formed close to the sides of a semiconductor chip 20 before a wiring film WF is positioned on the semiconductor chip 20. The first supporting parts 51 and 53 support the wiring film WF. An adhesive part 37 included in the wiring film WF is adhered to the first supporting parts 51 and 53. The first supporting parts 51 and 53 may be triangular as illustrated in FIG. 5 or square as illustrated in FIG. 6. These supporting parts 51 and 53 may reduce stress on the base film 30 and wires 32 during the connection process and may alter the package dimensions to correspond to other components (not shown) in the electronic devices that include the packages.

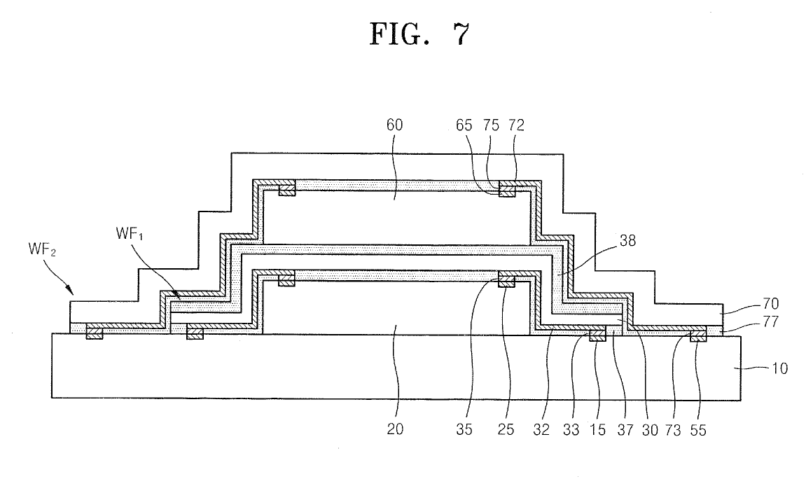

FIG. 7 is a sectional view of a semiconductor package according to an embodiment of the present invention. The semiconductor package of the embodiment of FIG. 7 is similar to the semiconductor package described with reference to the embodiment illustrated in FIG. 4C, except for the following.

Referring to FIG. 7, a first semiconductor chip 20 including first chip pad electrodes 25 is positioned on a board 10 including first board pad electrodes 15 and second board pad electrodes 55. A first wiring film WF1 is positioned on the board 10 and the first semiconductor chip 20. The first wiring film WF1 includes a first base film 30, first wires 32 arranged on the lower surface of the first base film 30, first bumps 33 and 35 respectively arranged on the ends of the first wires 32, and a first adhesive layer 37 covering the first wires 32 and the first bumps 33 and 35. The first wiring film WF1 may further include an upper adhesive layer 38 positioned on the upper surface of the first base film 30.

The first wiring film WF1 and the board 10 are aligned so that the first bumps 33 and 35 of the first wiring film WF1 respectively correspond to the first pad electrodes 15 and 25. Subsequently, heat and pressure are applied to the first wiring film WF1 so that the first bumps 33 and 35 are respectively connected to the first pad electrodes 15 and 25.

As a result, the first wires 32, which are positioned on the lower surface of the first base film 30, electrically couple the first board pad electrodes 5 with the first chip pad electrodes 25. The first adhesive layer 37 is positioned at both sides of the first bumps 33 and 35, to cover the first wires 32 and to contact the board 10 and the first semiconductor chip 20.

A second semiconductor chip 60 including second chip pad electrodes 65 is positioned on the first wiring film WF1. The second semiconductor chip 60 is connected to the first wiring film WF1 by the upper adhesive layer 38. When using the first wiring film WF1 including the upper adhesive layer 38, it is possible to stack the second semiconductor chip 60 without any additional adhesive layer, thereby reducing the process cost.

A second wiring film WF2 is positioned on the board 10 and the second semiconductor chip 60. The second wiring film WF2 includes a second base film 70, second wires 72 arranged on the lower surface of the second base film 70, second bumps 73 and 75 respectively arranged on the ends of the second wires 72, and a second adhesive layer 77 covering the second wires 72 and the second bumps 73 and 75.

The second wiring film WF2 and the board 10 are aligned so that the second bumps 73 and 75 respectively correspond to the second pad electrodes 55 and 65. Subsequently, heat and pressure are applied to the second wiring film WF2 so that the second bumps 73 and 75 are respectively electrically connected to the second pad electrodes 55 and 65.

As a result, the second wires 72, which are positioned on the lower surface of the second base film 70, electrically couple the second board pad electrodes 55 and the second chip pad electrodes 65. The second adhesive layer 77 is positioned at both sides of the second bumps 73 and 75, to cover the second wires 72 and to contact the board 10 and the second semiconductor chip 60.

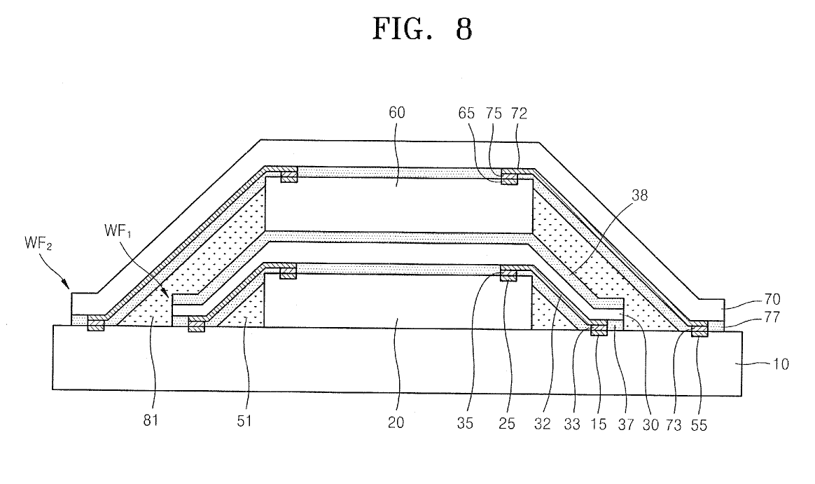

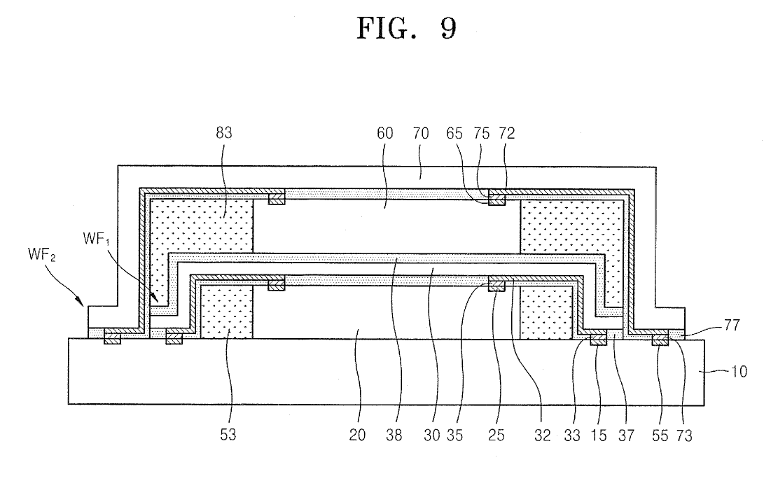

FIGS. 8 and 9 are sectional views of semiconductor packages according to embodiments of the present invention, The semiconductor packages of the embodiments illustrated in FIGS. 8 and 9 are similar to the semiconductor package described with reference to the embodiment illustrated in FIG. 7, except for the following.

Referring to FIGS. 8 and 9, first supporting parts 51 and 53 are formed close to the sides of a first semiconductor chip 20 before a first wiring film WF1 is positioned on the first semiconductor chip 20. The first supporting parts 51 and 53 support the first wiring film WF1. A first adhesive part 37 included in the first wiring film WF1 is adhered to the first supporting parts 51 and 53. The first supporting parts 51 and 53 may be triangular as illustrated in FIG. 8 or square as illustrated in FIG. 9.

Second supporting parts 81 and 83 are formed close to the sides of a second semiconductor chip 60 before a second wiring film WF2 is positioned on the second semiconductor chip 60. The second supporting parts 81 and 83 support the second wiring film WF2. A second adhesive part 77 included in the second wiring film WF2 is adhered to the second supporting parts 81 and 83. The second supporting parts 81 and 83 may be triangular as illustrated in FIG. 8 or square as illustrated in FIG. 9. The first and second supporting parts 51, 53 and 81, 83 may respectively reduce stress on the base films 30 and 70, and wires 32 and 72 during the connection process and may alter the package dimensions to correspond to other components (not shown) in the electronic devices that include the packages.

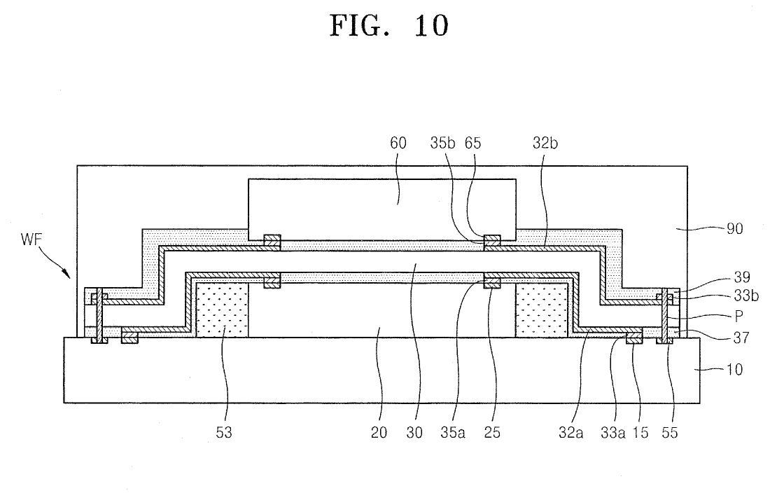

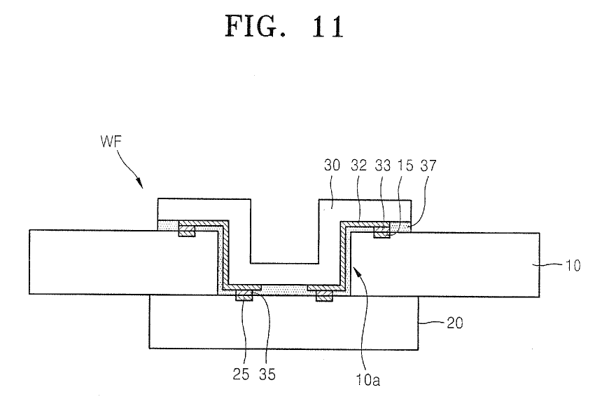

FIG. 10 is a sectional view of a semiconductor package according to another embodiment of the present invention.

Referring to FIG. 10, a first semiconductor chip 20 including first chip pad electrodes 25 is positioned on a board 10 including first board pad electrodes 15 and second board pad electrodes 55. The wiring film WF described in reference to FIG. 2 is positioned on the board 10 and the first semiconductor chip 20.

The wiring film WF and the board 10 are aligned so that first bumps 33a and 35a of the wiring film WF respectively correspond to the first pad electrodes 15 and 25. Subsequently, heat and pressure are applied so that the first bumps 33a and 35a are respectively electrically connected to the first pad electrodes 15 and 25.

A second semiconductor chip 60 including second chip pad electrodes 65 is positioned to be flipped on the wiring film WF. The second semiconductor chip 60 and the board 10 are aligned so that the second chip pad electrodes 65 respectively correspond to second bumps 35b positioned in the middle portion the wiring film WF. Subsequently, heat and pressure are applied so that the second chip pad electrodes 65 are respectively electrically connected to the second bumps 35b. Additionally, the second adhesive 39 formed on the second surface of the wiring film WF may be used to adhere the second semiconductor chip 60 to the package.

Among the second bumps 33b and 35b of the wiring film WF, the second bumps 33b positioned at outside portions of the wiring film WF are connected to the second board pad electrodes 55 by conductive pins P.

Subsequently, a molding layer 90 is formed on the board 10, to cover the second semiconductor chip 60 and the wiring film WF. The molding layer 90 contacts the second adhesive layer 39.

FIG. 11 is a sectional view of a semiconductor package according to an embodiment of the present invention. The semiconductor package of the embodiment of FIG. 11 is similar to the semiconductor package described with reference to the embodiment illustrated in FIG. 4C, except for the following.

Referring to FIG. 11, a board 10 including a through-hole 10a formed at its middle part is provided. Board pad electrodes 15 are arranged on a first surface of the board 10, adjacent to the through-hole 10a.

A semiconductor chip 20 is positioned under the board 10 on a second surface of the board that is opposite to the first surface of the board 10. The semiconductor chip 20 includes chip pad electrodes 25 in its middle part. The chip pad electrodes 25 are exposed by the through-hole 10a.

The wiring film WF described with reference to FIG. 1C is positioned on the first surface of the board 10. The wiring film WF and the board 10 are aligned so that bumps 33 and 35 of the wiring film WF respectively correspond to the pad electrodes 15 and 25. Subsequently, heat and pressure are applied so that the bumps 33 and 35 are respectively connected to the pad electrodes 15 and 25. In this process, the wiring film WF is disposed through the through-hole 10a to electrically connect the chip pad electrodes 25 with the bumps 35. Additionally, the adhesive layer 37 may be used to adhere the chip to the board 10.

As a result, a board on chip (BOC) package is realized, using the wiring film WF including the wires 32.

In accordance with the present invention as described above, the wiring film including wires is used to electrically couple the board pad electrodes to the chip pad electrodes, thereby enabling a semiconductor package to be thin because there is no problem relating to the loop height, unlike the wire bonding method. Additionally, the manufacturing process is simplified over a flip chip method because no redistribution layer is needed to redistribute wires on the board or semiconductor chip, which also reduces the manufacturing process costs. Furthermore, the wiring film includes the adhesive layer on the bumps, thereby requiring no additional adhesive layers between the wiring film and the board or between the wiring film and the semiconductor chip. The adhesive layer is positioned at both sides of the bumps, thereby maintaining the electrical connection between the bumps and the pad electrodes even if the package is bent; thereby improving the reliability of the package.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A wiring film comprising:
a base film;
first wires arranged on a first surface of the base film;
first bumps respectively positioned at ends of the first wires; and
a first adhesive layer covering the first wires and the first bumps.

2. The wiring film of claim 1, wherein a height of the first adhesive layer is substantially equal to or greater than a height of the first bump from the first surface of the base film.

3. The wiring film of claim 2, wherein the height of the first adhesive layer is about 1.1 times or less the height of the first bump.

4. The wiring film of claim 1, further comprising:
a first protection layer positioned on the first adhesive layer.

5. The wiring film of claim 1, further comprising:
a second adhesive layer positioned on a second surface opposite the first surface of the base film.

6. The wiring film of claim 5, further comprising:
a second protection layer positioned on the second adhesive layer.

7. The wiring film of claim 1, further comprising:
second wires arranged on a second surface opposite the first surface of the base film;
second bumps respectively positioned at ends of the second wires; and
a second adhesive layer covering the second wires and the second bumps.

8. The wiring film of claim 7, further comprising:
a second protection layer positioned on the second adhesive layer.

9. The wiring film of claim 1, wherein the first wires are formed by at least one of printing, jetting, or imprinting.

10. A semiconductor package comprising:
a board including first board pad electrodes;
a first semiconductor chip positioned on the board and including first chip pad electrodes; and
a first wiring film positioned on the board and the first semiconductor chip, wherein the first wiring film comprises:
a first base film,
first wires arranged on a lower surface of the first base film and electrically coupling the first board pad electrodes to the first chip pad electrodes,
first bumps respectively arranged between the first wires and the first pad electrodes, and
a first adhesive layer positioned at both sides of the first bumps, the first adhesive layer covering the first wires and contacting the first semiconductor chip and the board.

11. The semiconductor package of claim 10, further comprising:
a first supporting part positioned close to sides of the first semiconductor chip and supporting the first base film.

12. The semiconductor package of claim 10, wherein the board further comprises second board pad electrodes and the semiconductor package further comprises:
a second semiconductor chip positioned on an upper surface of the first base film and including second chip pad electrodes; and
a second wiring film connected to the second semiconductor chip and the board, wherein the second wiring film comprises:
a second base film,
second wires arranged on a lower surface of the second base film and electrically coupling the second board pad electrodes to the second chip pad electrodes,
second bumps respectively arranged between the second wires and the second pad electrodes, and
a second adhesive layer positioned at both sides of the second bumps, the second adhesive layer covering the second wires and contacting the board and the second semiconductor chip.

13. The semiconductor package of claim 12, wherein the first wiring film further comprises an upper adhesive layer positioned on the upper surface of the first base film, and the second semiconductor chip is connected to the first wiring film by the upper adhesive layer.

14. The semiconductor package of claim 12, further comprising:
a second supporting part positioned close to sides of the second semiconductor chip and supporting the second base film.

15. The semiconductor package of claim 10, wherein the board further includes second board pad electrodes, and the first wiring film comprises:
second wires arranged on the upper surface of the first base film;
second bumps respectively positioned on ends of the second wires; and
a second adhesive layer positioned at both sides of the second bumps and covering the second wires, and
wherein the semiconductor package further comprises a second semiconductor chip which is flipped and attached to the first wiring film by the second adhesive layer, the second semiconductor chip including second chip pad electrodes electrically connected to the second bumps positioned at one end of the second wires.

16. The semiconductor package of claim 15, further comprising:
a molding layer positioned on the board, the molding layer covering the second semiconductor chip and the first wiring film, and contacting the second adhesive layer.

17. A method of fabricating a semiconductor package, comprising:
positioning a first semiconductor chip including first chip pad electrodes on a board including first board pad electrodes;
positioning a first wiring film on the board and the first semiconductor chip, the first wiring film comprising a first base film, first wires arranged on a first surface of the first base film, first bumps respectively positioned on ends of the first wires, and a first adhesive layer covering the first wires and the first bumps; and
respectively electrically connecting the first bumps to the first pad electrodes.

18. The method of claim 17, wherein electrically connecting the first bumps to the first pad electrodes includes applying heat and pressure.

19. The method of claim 17, further comprising:
forming a first supporting part close to sides of the first semiconductor chip, prior to the positioning of the first wiring film on the board.

20. The method of claim 17, wherein the board further comprises second board pad electrodes and the method further comprises:
positioning a second semiconductor chip including second chip pad electrodes on the first wiring film;
positioning a second wiring film on the board and the second semiconductor chip, the second wiring film comprising a second base film, second wires arranged on a first surface of the second base film, second bumps respectively positioned on ends of the second wires, and a second adhesive layer covering the second wires and the second bumps; and
respectively electrically connecting the second bumps to the second pad electrodes.

21. The method of claim 20, wherein the first wiring film further comprises an upper adhesive layer positioned on an upper surface of the first base film, and the second semiconductor chip is connected to the first wiring film by the upper adhesive layer.

22. The method of claim 20, further comprising:
forming a second supporting part close to sides of the second semiconductor chip, prior to the positioning of the second wiring film on the board.

23. The method of claim 17, wherein the board further comprises second board pad electrodes, and the first wiring film further comprises second wires arranged on a second surface opposite the first surface of the first base film, second bumps respectively positioned at ends of the second wires, and a second adhesive layer covering the second wires and the second bumps, and
wherein the method comprises:
flipping and positioning a second semiconductor chip including second chip pad electrodes on the first wiring film; and
respectively electrically connecting the second pad electrodes to the second bumps.

24. The method of claim 23, further comprising:
forming a molding layer on the board, the molding layer covering the second semiconductor chip and the first wiring film and contacting the second adhesive layer.

25. A semiconductor package comprising:
a board including first board pad electrodes disposed in an outer portion of an upper surface of the board;
a first semiconductor chip positioned on a substantially central portion of the board, the first semiconductor chip including first chip pad electrodes on an upper surface of the first semiconductor chip; and
a first wiring film positioned on the board and the first semiconductor chip, wherein the first wiring film comprises:
a first base film,
first wires arranged on a lower surface of the first base film to electrically couple the first board pad electrodes to the first chip pad electrodes,
first bumps respectively arranged between the first wires and the first chip pad electrodes to respectively electrically couple the first wires to the first chip pad electrodes,
second bumps respectively arranged between the first wires and the first board pad electrodes to respectively electrically couple the first wires to the first board pad electrodes, and
a first adhesive layer disposed between the first base film and the board having the first semiconductor chip, the first adhesive layer covering the first wires and adhering the first wiring film to the first semiconductor chip and the board.

26. The semiconductor package of claim 25, wherein the board further comprises second board pad electrodes disposed in the outer portion of the board and the semiconductor package further comprises:
an upper adhesive formed on the first wiring film;
a second semiconductor chip positioned on the upper adhesive and substantially aligned with the first semiconductor, the second semiconductor chip including second chip pad electrodes; and
a second wiring film positioned on the board having the first wiring film and second semiconductor chip, the second wiring film comprising:
a second base film,
second wires arranged on a lower surface of the second base film to electrically couple the second board pad electrodes to the second chip pad electrodes,
third bumps respectively arranged between the second wires and the second chip pad electrodes to respectively electrically couple the second wires to the second chip pad electrodes,
fourth bumps respectively arranged between the second wires and the second board pad electrodes to respectively electrically couple the second wires to the second board pad electrodes, and
a second adhesive layer disposed between the second base film and the board having the first wiring pattern and the second semiconductor chip, the second adhesive layer covering the second wires and adhering the second wiring film to the second semiconductor chip, the first wiring pattern, and the board.

27. The semiconductor package of claim 25, wherein the board further includes second board pad electrodes, and the first wiring film comprises:
second wires arranged on the upper surface of the first base film;
third and fourth bumps respectively positioned on ends of the second wires, the fourth bumps respectively electrically connected to the second board pad electrodes; and
a second adhesive layer covering the second wires on the upper surface of the first base film, and
wherein the semiconductor package further comprises a second semiconductor chip which is flipped and attached to the first wiring film by the second adhesive layer, the second semiconductor chip including second chip pad electrodes respectively electrically connected to the second wires through the third bumps.

28. The semiconductor package of claim 27, wherein the fourth bumps are respectively electrically connected to the second board pad electrodes though a plurality of conductive pins.

30. A semiconductor package comprising:
a board having an upper surface and a lower surface, the board including first board pad electrodes formed on the upper surface of the board at an outer portion of the board and including a hole formed through the board at a substantially central portion of the board;
a semiconductor chip positioned on the second surface of the board and including chip pad electrodes formed on an upper surface of the semiconductor chip, wherein the chip pad electrodes are aligned with the hole in the board; and
a first wiring film positioned on the upper surface of the board and through the hole to be positioned on an exposed portion of the upper surface of the semiconductor chip, wherein the first wiring film comprises:
a first base film,
first wires arranged on a lower surface of the first base film and electrically coupling the first board pad electrodes to the first chip pad electrodes,
first bumps respectively arranged between the first wires and the first pad electrodes, and
a first adhesive layer positioned at both sides of the first bumps, the first adhesive layer covering the first wires and contacting the first semiconductor chip and the board.
